(19) United States
(12) Patent Application Publication
(10) Pub. No.: US 2021/0280429 A1
(43) Pub. Date: Sep. 9, 2021

(54) SUBSTRATE PROCESSING SYSTEM AND SUBSTRATE PROCESSING METHOD

(71) Applicant: Tokyo Electron Limited, Tokyo (JP)

(72) Inventor: Satoshi OOKAWA, Koshi City, Kumamoto (JP)

(21) Appl. No.: 17/260,584

(22) PCT Filed: Jul. 18, 2019
(86) PCT No.: PCT/JP2019/028312

§ 371 Date: Jan. 15, 2021

(30) Foreign Application Priority Data
Jul. 26, 2018 (JP) 2018-140438

(51) Int. Cl. H01L 21/306; H01L 21/304; B05B 12/12; B24B 7/22; G01B 11/06; G01K 1/02

(52) U.S. Cl. CPC H01L 21/306; H01L 21/304; G01K 1/02; B24B 7/228; G01B 11/06; B05B 12/122

(57) ABSTRACT

A substrate processing system configured to process a substrate includes an etching apparatus configured to etch the substrate; and a control device configured to control the etching apparatus. The etching apparatus includes a liquid supply nozzle configured to supply a processing liquid onto the substrate; a thickness measurement device provided as one body with the liquid supply nozzle, and configured to measure a thickness of the substrate without being in contact with the substrate; and a moving mechanism configured to move the liquid supply nozzle and the thickness measurement device in a horizontal direction. The control device controls the liquid supply nozzle, the thickness measurement device and the moving mechanism such that the thickness of the substrate is measured by the thickness measurement device while the liquid supply nozzle and the thickness measurement device are being moved in the horizontal direction.

### TECHNICAL FIELD

The various aspects and embodiments described herein pertain generally to a substrate processing system and a substrate processing method.

### BACKGROUND

Patent Document 1 describes an etching apparatus configured to perform wet etching on a thin film on a semiconductor substrate. The etching apparatus is equipped with a chemical liquid discharge nozzle, an optical cable and an optical film thickness measurement device. The chemical liquid discharge nozzle discharges a chemical liquid for the wet etching onto the semiconductor substrate. The optical cable is configured to guide light so that the light reaches a front surface of the substrate through the chemical liquid and, also, to receive reflection light reflected from the front surface of the semiconductor substrate through the chemical liquid. At least a part of this optical cable is accommodated within the chemical liquid discharge nozzle. The optical film thickness measurement device measures a film thickness of an etching target film on the semiconductor substrate based on information obtained from the reflection light.

### PRIOR ART DOCUMENT

Patent Document 1: Japanese Patent Laid-open Publication No. H11-354489

### DISCLOSURE OF THE INVENTION

### Problems to be Solved by the Invention

Exemplary embodiments provide a technique capable of improving uniformity of an etching processing within a surface of a substrate by investigating, within the surface of the substrate, a thickness of the substrate being etched.

### Means for Solving the Problems

In an exemplary embodiment, a substrate processing system configured to process a substrate includes an etching apparatus configured to etch the substrate; and a control device configured to control the etching apparatus. The etching apparatus includes a liquid supply nozzle configured to supply a processing liquid onto the substrate; a thickness measurement device provided as one body with the liquid supply nozzle, and configured to measure a thickness of the substrate without being in contact with the substrate; and a moving mechanism configured to move the liquid supply nozzle and the thickness measurement device in a horizontal direction. The control device controls the liquid supply nozzle, the thickness measurement device and the moving mechanism such that the thickness of the substrate is measured by the thickness measurement device while the liquid supply nozzle and the thickness measurement device are being moved in the horizontal direction.

### Effect of the Invention

According to the exemplary embodiments, it is possible to improve uniformity of an etching processing within a surface of a substrate by investigating, within the surface of the substrate, a thickness of the substrate being etched.

### BRIEF DESCRIPTION OF THE DRAWINGS

FIG. 1 is a plan view schematically illustrating a configuration of a wafer processing system according to a first exemplary embodiment.

FIG. 2 is a side view illustrating a schematic structure of a combined wafer.

FIG. 3 is a longitudinal cross sectional view illustrating a schematic configuration of a wet etching apparatus.

FIG. 4 is a transversal cross sectional view illustrating a schematic configuration of the wet etching apparatus.

FIG. 5 is a longitudinal cross sectional view illustrating a schematic configuration of a liquid supply nozzle.

FIG. 6 is a flowchart illustrating major processes of a wafer processing.

FIG. 7A to FIG. 7E are explanatory diagrams illustrating the major processes of the wafer processing.

FIG. 8 is a plan view schematically illustrating a configuration of a wafer processing system according to a second exemplary embodiment.

FIG. 9 is a longitudinal cross sectional view illustrating a schematic configuration of a wet etching apparatus according to another exemplary embodiment.

FIG. 10 is a longitudinal cross sectional view illustrating a schematic configuration of a wet etching apparatus according to yet another exemplary embodiment.

### DETAILED DESCRIPTION

In a manufacturing process for a semiconductor device, a semiconductor wafer (hereinafter, simply referred to as “wafer”) having devices such as a plurality of electronic circuits formed on a front surface thereof is thinned by grinding a rear surface of the wafer.

If the rear surface of the wafer is ground, a damage layer including a crack or a flaw is formed on the rear surface of the wafer. Since the damage layer causes a residual stress on the wafer, a flexural strength of a chip obtained by dicing the wafer is weakened, resulting in cracking or breakage of the chip. Thus, a process of removing the damage layer is performed.

The damage layer is removed by, for example, wet etching. This wet etching is performed by the etching apparatus described in, for example, Patent Document 1. The etching apparatus is equipped with the chemical liquid discharge nozzle, the optical cable and the optical film thickness measurement device described above, and measures an etching amount in an etching processing. In this etching apparatus, however, the etching amount only at a certain position of the wafer is measured, and a distribution of the etching amount within the entire surface of the wafer cannot be investigated. As a result, the etching may not be performed uniformly within the surface of the wafer. In this regard, there is still a room for improvement.

The present disclosure provides a technique capable of improving uniformity of the etching processing within the surface of the wafer by investigating, within the surface of the wafer, a thickness of the wafer being etched. Hereinafter, a wafer processing system as a substrate processing system and a wafer processing method as a substrate processing method according to exemplary embodiments will be described with reference to the accompanying drawings. In the specification and the drawings, parts having same functions and configurations will be assigned same reference numerals, and redundant description will be omitted.

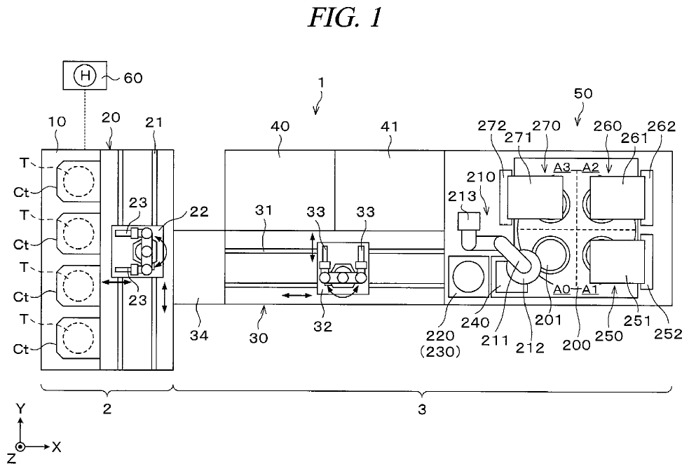

First, a configuration of a wafer processing system according to a first exemplary embodiment will be explained. FIG. 1 is a plan view schematically illustrating a configuration of a wafer processing system 1.

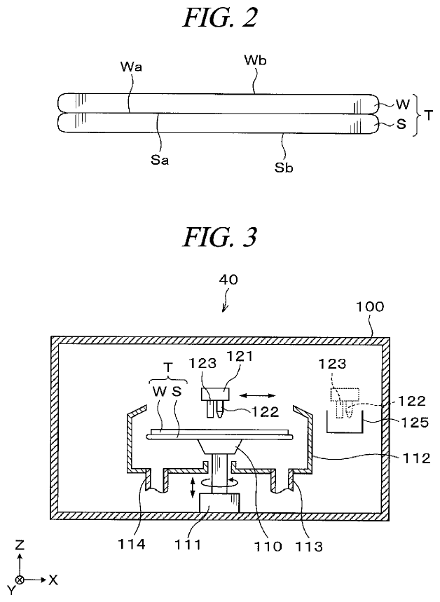

In the wafer processing system 1, by performing required processings on a combined wafer T as a substrate in which a processing target wafer W and a support wafer S are bonded to each other, the processing target wafer W is thinned, as shown in FIG. 2. Hereinafter, in the processing target wafer W, a surface bonded to the support wafer S will be referred to as a front surface Wa, and a surface opposite to the front surface Wa will be referred to as a rear surface Wb. Likewise, in the support wafer S, a surface bonded to the processing target wafer W will be referred to as a front surface Sa, and a surface opposite to the front surface Sa will be referred to as a rear surface Sb.

The processing target wafer W is a semiconductor wafer such as, but not limited to, a silicon wafer, and has a plurality of devices formed on the front surface Wa thereof. Further, a peripheral portion of the processing target wafer W is chamfered, and a thickness of the peripheral portion decreases toward a leading end thereof on a cross section thereof.

The support wafer S is a wafer which supports the processing target wafer W. Further, the support wafer S serves as a protection member which protects the devices on the front surface Wa of the processing target wafer W. Further, if the support wafer S serves as a device wafer, a plurality of devices is formed on the front surface Sa of the support wafer S, the same as in the processing target wafer W.

As depicted in FIG. 1, the wafer processing system 1 includes a carry-in/out station 2 and a processing station 3 connected as one body. The processing station 3 is equipped with various kinds of processing apparatuses configured to perform required processings on the combined wafer T.

The carry-in/out station 2 is equipped with a cassette placing table 10. In the shown example, a plurality of, for example, four cassettes Ct can be arranged on the cassette placing table 10 in a row in the X-axis direction. Further, the number of the cassettes Ct placed on the cassette placing table 10 is not limited to the example of the present exemplary embodiment but can be selected as required.

In the carry-in/out station 2, a wafer transfer section 20 is provided adjacent to the cassette placing table 10. Provided in the wafer transfer section 20 is a wafer transfer device 22 configured to be movable on a transfer path 21 which is elongated in the X-axis direction. The wafer transfer device 22 is equipped with, for example, two transfer arms 23 each configured to hold and transfer the combined wafer T. Each transfer arm 23 is configured to be movable in a horizontal direction and a vertical direction and pivotable around a horizontal axis and a vertical axis. Further, the configuration of the transfer arm 23 is not limited to the exemplary embodiment, and various other configurations may be adopted.

A wafer transfer section 30 is provided in the processing station 3. Provided in the wafer transfer section 30 is a wafer transfer device 32 configured to be movable on a transfer path 31 which is elongated in the X-axis direction. The wafer transfer device 32 is configured to be capable of transferring the combined wafer T to/from a transition device 34, wet etching apparatuses 40 and 41, and a grinding apparatus 50 to be described later. Further, the wafer transfer device 32 is equipped with, for example, two transfer arms 33 configured to hold and transfer the combined wafer T. Each transfer arm 33 is configured to be movable in a horizontal direction and a vertical direction and pivotable around a horizontal axis and a vertical axis. Further, the configuration of the transfer arm 23 is not limited to the present exemplary embodiment, and various other configurations may be adopted.

The transition device 34 is provided between the wafer transfer section 20 and the wafer transfer section 30 to deliver the combined wafer T.

The wet etching apparatuses 40 and 41 are arranged at a positive Y-axis side of the wafer transfer section 30 in this sequence in the X-axis direction from the carry-in/out station 2. In the wet etching apparatuses 40 and 41, wet etching is performed on the rear surface Wb of the processing target wafer W by using an etching liquid such as, but not limited to, fluoric acid.

The grinding apparatus 50 is disposed at a positive X-axis side of the wafer transfer section 30. In the grinding apparatus 50, a processing including grinding, cleaning and so forth is performed on the processing target wafer W.

The above-described wafer processing system 1 is equipped with a control device 60. The control device 60 is, for example, a computer, and includes a program storage (not shown). A program for controlling a processing of the combined wafer T in the wafer processing system 1 is stored in the program storage. Further, the program storage also stores therein a program for implementing a wafer processing to be described later in the wafer processing system 1 by controlling the above-described various processing apparatuses and a driving system such as the transfer devices. Further, the programs may be recorded in a computer-readable recording medium H, and may be installed from this recording medium H to the control device 60.

Now, the wet etching apparatuses 40 and 41 will be described. The wet etching apparatuses 40 and 41 have the same configuration. In the following, the configuration of the wet etching apparatus 40 will be explained.

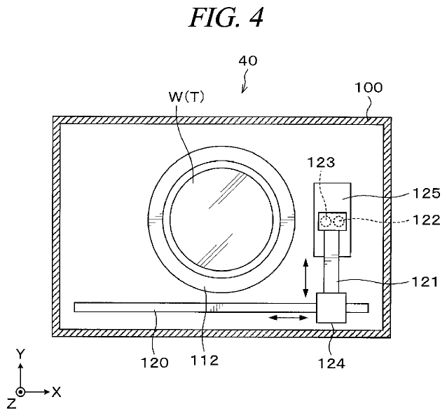

The wet etching apparatus 40 has a processing vessel 100 having a hermetically sealable inside, as illustrated in FIG. 3 and FIG. 4. A carry-in/out opening (not shown) for the combined wafer T is formed in a side surface of the processing vessel 100 near the wafer transfer section 30, and an opening/closing shutter (not shown) is provided at this carry-in/out opening.

Provided at a central portion within the processing vessel 100 is a spin chuck 110 configured to hold and rotate the combined wafer T in the state the processing target wafer W is placed at an upper side and the support wafer S is placed at a lower side. The spin chuck 110 has a horizontal top surface, and a suction hole (not shown) for suctioning, for example, the combined wafer T is formed in the top surface. The combined wafer T can be attracted to and held on the spin chuck 110 by the suctioning through this suction hole.

A chuck driving unit 111 equipped with, for example, a motor is provided under the spin chuck 110. The spin chuck 110 is configured to be rotated by the chuck driving unit 111. Further, the chuck driving unit 111 is equipped with an elevation driving source such as a cylinder, and the spin chuck 110 can be moved up and down.

A cup 112 configured to receive a liquid scattering or falling from the combined wafer T is provided around the spin chuck 110. A drain pipe 113 through which the received liquid is drained and an exhaust pipe 114 through which an atmosphere within the cup 112 is exhausted to evacuate the cup 112 are connected to a bottom surface of the cup 112.

As depicted in FIG. 4, a rail 120 extending in the X-axis direction (a left-right direction in FIG. 4) is provided at a negative Y-axis side (a lower side in FIG. 4) of the cup 112. The rail 120 is elongated from a position outside the cup 112 at a negative X-axis side (a left side in FIG. 4) thereof to a position outside the cup 112 at a positive X-axis side (a right side in FIG. 4) thereof. An arm 121 is mounted to the rail 120.

This arm 121 is equipped with a liquid supply nozzle 122 configured to supply a rinse liquid and an etching liquid as a processing liquid onto the processing target wafer W; and a temperature measurement device 123 configured to measure a temperature of the processing target wafer W, as depicted in FIG. 3 and FIG. 4. The arm 121 is configured to be movable in the X-axis direction along the rail 120 by a driving unit 124 shown in FIG. 4. Accordingly, the liquid supply nozzle 122 and the temperature measurement device 123 can be moved to a position above a central portion of the processing target wafer W within the cup 112 from a standby section 125 provided at an outside of the cup 112 at a positive Y-axis side thereof, and, also, can be moved above the processing target wafer W in a diametrical direction of the processing target wafer W. Furthermore, the arm 121 moves the liquid supply nozzle 122 and the temperature measurement device 123 in the Y-axis direction by the driving unit 124. Further, the arm 121 is configured to be moved up and down by the driving unit 124, and is thus capable of adjusting a height of the liquid supply nozzle 122 and the temperature measurement device 123. In the present exemplary embodiment, the rail 120, the arm 121 and the driving unit 124 constitute a moving mechanism of the present disclosure.

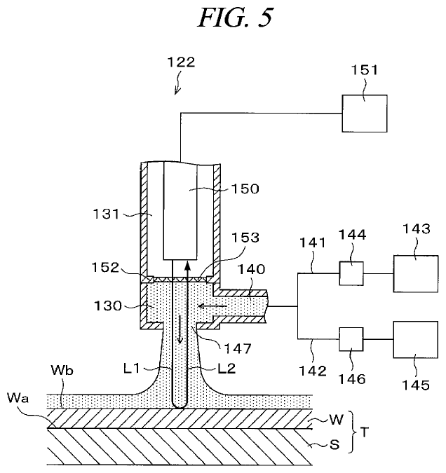

As illustrated in FIG. 5, the liquid supply nozzle 122 includes a first case 130 in which the etching liquid and the rinse liquid flow; and a second case 131 provided above the first case 130 and accommodating therein a sensor 150 to be described later. An inside of the first case 130 and an inside of the second case 131 are provided independently from each other so that the etching liquid and the rinse liquid flowing in the first case 130 is not introduced into the second case 131.

The first case 130 is connected with a supply line 140 through which the etching liquid and the rinse liquid are supplied. The supply line 140 is branched into an etching liquid supply line 141 and a rinse liquid supply line 142 at an opposite side from the first case 130. The etching supply line 141 is connected to an etching liquid source 143 which stores the etching liquid therein. Further, the etching liquid supply line 141 is equipped with a valve 144 configured to control a supply of the etching liquid. The rinse liquid supply line 142 is connected to a rinse liquid source 145 which stores therein the rinse liquid, for example, pure water. Further, the rinse liquid supply line 142 is equipped with a valve 146 configured to control a supply of the rinse liquid.

A supply opening 147 for supplying the etching liquid and the rinse liquid is formed in a bottom surface (a leading end of the liquid supply nozzle 122) of the first case 130. Infrared light L1 and reflection light L2 to be described later also pass through this supply opening 147.

In the liquid supply nozzle 122, by opening the valve 144 while closing the valve 146, the etching liquid is supplied onto the rear surface Wb of the processing target wafer W, so that the rear surface Wb is etched. To elaborate, the etching liquid supplied from the etching liquid source 143 flows through the etching liquid supply line 141, the supply line 140 and the first case 130 and is then supplied onto the rear surface Wb of the processing target wafer W from the supply opening 147. Meanwhile, by opening the valve 146 while closing the valve 144, the rinse liquid is supplied onto the rear surface Wb of the processing target wafer W, so that the rear surface Wb is rinsed. In the liquid supply nozzle 122, by controlling the valves 144 and 146 as stated above, the supply of the etching liquid and the rinse liquid can be switched.

The sensor 150 as a thickness measurement device is provided within the second case 131. That is, the liquid supply nozzle 122 and the sensor 150 are configured as one body. The sensor 150 is configured to measure a thickness of the processing target wafer W in a non-contact manner without being in contact with the processing target wafer W. By way of example, the sensor 150 radiates the infrared light L1 toward the rear surface Wb of the processing target wafer W, and receives the reflection light L2 reflected from the rear surface Wb. Here, the light radiated from the sensor 150 is not limited to the infrared light as long as the sensor 150 is capable of measuring the thickness of the processing target wafer W in the non-contact manner. By way of non-limiting example, a SLD (Super Luminescent Diode) or a LED (Light Emitting diode) may be used as a light source.

The sensor 150 is connected with an operation unit 151. The operation unit 151 is configured to calculate the thickness of the processing target wafer W based on a waveform of the reflection light L2 received by the sensor 150. Further, the operation unit 151 may be provided in, for example, the control device 60.

A bottom plate 152 is provided at a lower end of the second case 131, and the first case 130 and the second case 131 are separated by this bottom plate 152. A window 153 is provided at a central portion of the bottom plate 152. The window 153 is made of a material which is resistant against the etching liquid and is capable of transmitting the aforementioned infrared light L1 and reflection light L2. By way of non-limiting example, glass (quartz, SiO₂) or a resin may be used.

In the liquid supply nozzle 122, the infrared light L1 radiated from the sensor 150 enters the first case 130 through the window 153 and reaches the rear surface Wb of the processing target wafer W through the supply opening 147. The infrared light L1 is reflected on the rear surface Wb, and the reflection light L2 is received by the sensor 150 after passing through the supply opening 147, the first case 130 and the window 153. Then, the thickness of the processing target wafer W is calculated in the operation unit 151.

Timing for measuring the thickness of the processing target wafer W may be set as required. By way of example, when the thickness of the processing target wafer W is measured during an etching processing, the infrared light L1 passes through the inside of the first case 130 filled with the etching liquid, and reaches the rear surface Wb from the supply opening 147 after passing through the etching liquid. Further, the reflection light L2 also passes through the etching liquid from the rear surface Wb, and reaches the first case 130 through the supply opening 147. Accordingly, both the infrared light L1 and the reflection light L2 pass through the etching liquid and do not pass through the atmosphere. Therefore, a refractive index or the like of the infrared light L1 and the reflection light L2 can be maintained constant without being fluctuated.

Further, the sensor 150 is provided within the liquid supply nozzle 122. Here, when the rear surface Wb of the processing target wafer W is etched as will be described later, the etching liquid is supplied while the liquid supply nozzle 122 is moved within the surface of the wafer in order to improve uniformity of the etching within the surface of the wafer. At this time, since the sensor 150 is also moved within the surface of the wafer, the thickness of the processing target wafer W can be measured within the entire surface thereof during the etching processing.

Further, the timing for measuring the thickness of the processing target wafer W may be during a rinsing processing. In such a case, the thickness of the processing target wafer W is measured while supplying the rinse liquid. Both the infrared light L1 and the reflection light L2 pass through the rinse liquid and maintained constant. Thus, the thickness of the processing target wafer W can be measured accurately. Further, since the rinse liquid is supplied to the processing target wafer W, the thickness of the processing target wafer W is not changed when it is measured.

Moreover, the timing for measuring the thickness of the processing target wafer W may be before the etching processing or after the rinsing processing. In such a case, neither the etching liquid nor the rinse liquid exists within the first case 130, and the etching liquid and the rinse liquid are not supplied from the supply opening 147. In such a case, both the infrared light L1 and the reflection light L2 pass through the atmosphere and can be maintained constant. Thus, the thickness of the processing target wafer W can still be measured accurately. Further, prior to the etching processing, the thickness of the processing target wafer W may be measured while supplying the rinse liquid. In such a case, since the rinse liquid is supplied to the processing target wafer W, the thickness of the processing target wafer W is not changed when it is measured.

The temperature measurement device 123 shown in FIG. 3 and FIG. 4 measures a temperature of the processing target wafer W in the non-contact manner without being in contact with the processing target wafer W. A commonly known thermometer is used as this temperature measurement device 123. By way of example, a radiation thermometer may be used.

Here, since the sensor 150 uses the infrared light L1, the measured thickness may differ depending on the temperature of the processing target wafer W. Thus, temperature measurement data obtained by the temperature measurement device 123 are feedbacked to the operation unit 151. In such a case, the operation unit 151 corrects the thickness of the processing target wafer W based on the temperature measurement data. As a result, the thickness of the processing target wafer W can be measured more accurately. Furthermore, since an etching rate depends on a temperature, it is important to measure the temperature with the temperature measurement device 123 as in the present exemplary embodiment.

Moreover, the temperature measurement device 123 is supported at the arm 121 and disposed adjacent to the liquid supply nozzle 122. By way of example, the temperature of the processing target wafer W may be locally high or low within the surface of the wafer. Since, however, a temperature of the processing target wafer W at a thickness measurement point can be measured by the temperature measurement device 123 according to the present exemplary embodiment, it is possible to correct the thickness of the processing target wafer W accurately, coping with a local variation of the temperature.

Now, the grinding apparatus 50 shown in FIG. 1 will be explained. The grinding apparatus 50 includes a rotary table 200, a transfer unit 210, a processing unit 220, a first cleaning unit 230, a second cleaning unit 240, a rough grinding unit 250, an intermediate grinding unit 260 and a finishing grinding unit 270.

The rotary table 200 is configured to be rotated by a rotating mechanism (not shown). Four chucks 201 configured to attract and hold the combined wafer T are provided on the rotary table 200. The chucks 201 are arranged on a circle concentric with the rotary table 200 at a regular distance therebetween, that is, an angular distance of 90 degrees therebetween. The four chucks 201 are configured to be moved to a delivery position A0 and processing positions A1 to A3 as the rotary table 200 is rotated. Further, the chucks 201 are held by a chuck base (not shown) and is configured to be rotated by a rotating mechanism (not shown).

In the present exemplary embodiment, the delivery position A0 is a position at a negative X-axis and negative Y-axis side of the rotary table 200. The second cleaning unit 240, the processing unit 220 and the first cleaning unit 230 are arranged at a negative X-axis side of the delivery position A0. The processing unit 220 and the first cleaning unit 230 are stacked in this sequence from the top. The first processing position A1 is a position at a positive X-axis and negative Y-axis side of the rotary table 200, and the rough grinding unit 250 is disposed thereat. The second processing position A2 is a position at a positive X-axis and positive Y-axis side of the rotary table 200, and the intermediate grinding unit 260 is disposed thereat. The third processing position A3 is a position at a negative X-axis and positive Y-axis side of the rotary table 200, and the finishing grinding unit 270 is disposed thereat.

The transfer unit 210 is a multi-joint robot equipped with a plurality of, for example, there arms 211. Each of the three arms 211 is configured to be rotatable. The arm 211 at a leading end is equipped with a transfer pad 212 configured to attract and hold the combined wafer T. The arm 211 at a base end is mounted to a moving mechanism 213 configured to move the arm 211 in a vertical direction. The transfer unit 210 having this configuration is capable of transferring the combined wafer T to/from the delivery position A0, the processing unit 220, the first cleaning unit 230 and the second cleaning unit 240.

In the processing unit 220, a direction of the combined wafer T before being subjected to a grinding processing in the horizontal direction is adjusted. By way of example, while rotating the combined wafer T held by a chuck (not shown), a position of a notch of the processing target wafer W is detected by a detector (not shown), and by adjusting the position of the notch, the direction of the combined wafer T in the horizontal direction is adjusted.

Further, in the processing unit 220, by irradiating laser light to an inside of the processing target wafer W from a laser head (not shown) while rotating the combined wafer T held by the chuck, a modification layer having an annular shape is formed. The laser light has penetrability for the processing target wafer W. This laser light is concentrated to a preset position within the processing target wafer W, and this preset position to which the laser light is concentrated is modified, so that the modification layer is formed.

In the first cleaning unit 230, the rear surface Wb of the processing target wafer W after being subjected to the grinding processing is cleaned, and more specifically cleaned by spin cleaning.

In the second cleaning unit 240, the rear surface Sb of the support wafer S is cleaned in the state that the processing target wafer W after being subjected to the grinding processing is held by the transfer pad 212, and, also, the transfer pad 212 is cleaned.

In the rough grinding unit 250, the rear surface Wb of the processing target wafer W is roughly ground. The rough grinding unit 250 is equipped with a rough grinder 251 having a rough grinding whetstone (not shown) configured to be rotated in a ring shape. Further, the rough grinder 251 is configured to be moved in the vertical direction and the horizontal direction along a supporting column 252. By respectively rotating the chuck 201 and the rough grinding whetstone while keeping the rear surface Wb of the processing target wafer W held by the chuck 201 in contact with the rough grinding whetstone and, further, by lowering the rough grinding whetstone, the rear surface Wb of the processing target wafer W is roughly ground.

In the intermediate grinding unit 260, the rear surface Wb of the processing target wafer W is ground to an intermediate level. A configuration of the intermediate grinding unit 260 is almost the same as the configuration of the rough grinding unit 250. The intermediate grinding unit 260 includes an intermediate grinder 261 equipped with an intermediate grinding whetstone (not shown); and a supporting column 262. Further, a particle size of abrasive grains of the intermediate grinding whetstone is smaller than a particle size of abrasive grains of the rough grinding whetstone.

In the finishing grinding unit 270, the rear surface Wb of the processing target wafer W is ground finely. A configuration of the finishing grinding unit 270 is almost the same as the configuration of the rough grinding unit 250 and the intermediate grinding unit 260. The finishing grinding unit 270 includes a finishing grinder 271 equipped with a finishing grinding whetstone (not shown); and a supporting column 272. Further, a particle size of abrasive grains of the finishing grinding whetstone is smaller than the particle size of the abrasive grains of the intermediate grinding whetstone.

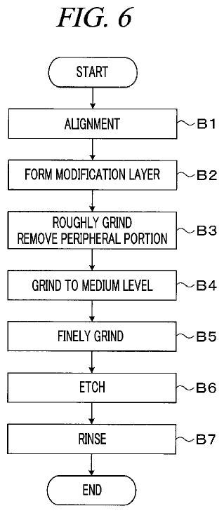

Now, a wafer processing performed by using the wafer processing system 1 having the above-described configuration will be described. FIG. 6 is a flowchart illustrating major processes of the wafer processing. In the present exemplary embodiment, a combined wafer T is previously formed by bonding a processing target wafer W and a support wafer S by a Van der Waals force and a hydrogen bond (intermolecular force) in a bonding apparatus (not shown) which is provided at an outside of the wafer processing system 1.

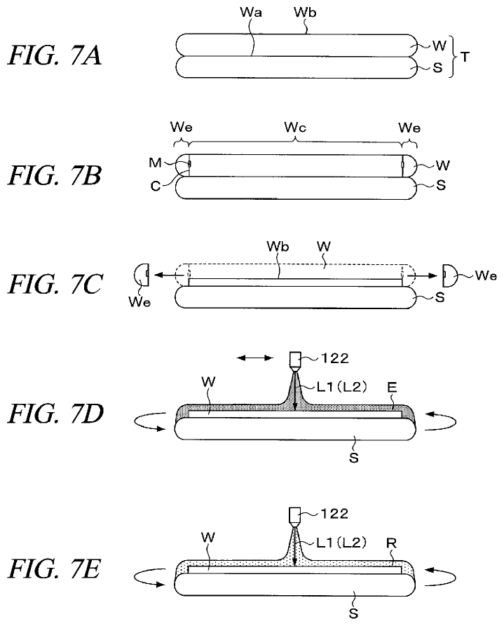

First, a cassette Ct having therein a multiple number of combined wafers T is placed on the cassette placing table 10 of the carry-in/out station 2, as shown in FIG. 7A.

Then, the combined wafer T is taken out of the cassette Ct by the wafer transfer device 22, and transferred into the transition device 34. Subsequently, the combined wafer T is taken out of the transition device 34 by the wafer transfer device 32, and transferred into the grinding apparatus 50.

The combined wafer T transferred to the grinding apparatus 50 is delivered into the processing unit 220. In the processing unit 220, a direction of the processing target wafer W in a horizontal direction is adjusted (process B1 of FIG. 6).

Further, in the processing unit 220, while rotating the processing target wafer W, laser light is irradiated to an inside of the processing target wafer W from the laser head. Then, as depicted in FIG. 7B, a modification layer M having an annular shape is formed within the processing target wafer W along a boundary between a peripheral portion We and a central portion We of the processing target wafer W (process B2 of FIG. 6). Further, a crack C develops from the modification layer M within the processing target wafer W and reaches a front surface Wa and a rear surface Wb.

Subsequently, the combined wafer T is transferred to the delivery position A0 from the processing unit 220 by the transfer unit 210, and delivered onto the chuck 201 at this delivery position A0. Then, the chuck 201 is moved to the first processing position A1. Then, the rear surface Wb of the processing target wafer W is roughly ground by the rough grinding unit 250, as shown in FIG. 7C (process B3 of FIG. 6).

In the process B3, the peripheral portion We of the processing target wafer W comes off and is removed, starting from the modification layer M and the crack C, as shown in FIG. 7C. Further, this removing of the peripheral portion (so-called edge trimming) is performed to suppress the peripheral portion We of the processing target wafer W after being ground from having a sharp pointed shape (a so-called knife edge shape).

Subsequently, the chuck 201 is moved to the second processing position A2. Then, the rear surface Wb of the processing target wafer W is ground to a medium level by the intermediate grinding unit 260 (process B4 of FIG. 6). If the peripheral portion We is not completely removed in the above-described rough grinding unit 250, the remaining peripheral portion We is completely removed in this intermediate grinding unit 260.

Next, the chuck 201 is moved to the third processing position A3. The rear surface Wb of the processing target wafer W is finely ground by the finishing grinding unit 270 (process B5 of FIG. 6).

Then, the chuck 201 is moved to the delivery position A0. Here, the rear surface Wb of the processing target wafer W is roughly cleaned by using a cleaning liquid nozzle (not shown). At this time, the cleaning is performed to remove a contaminant on the rear surface Wb to some extent.

Subsequently, the combined wafer T is transferred into the second cleaning unit 240 from the delivery position A0 by the transfer unit 210. Then, in the second cleaning unit 240, the rear surface Sb of the support wafer S is cleaned and dried in the state that the processing target wafer W is held by the transfer pad 212.

Afterwards, the combined wafer T is transferred into the first cleaning unit 230 from the second cleaning unit 240 by the transfer unit 210. In the first cleaning unit 230, the rear surface Wb of the processing target wafer W is cleaned finely by using the cleaning liquid nozzle (not shown). At this time, the rear surface Wb is cleaned to a required degree of cleanness to be dried.

Thereafter, the combined wafer T is transferred into the wet etching apparatus 40 by the wafer transfer device 32. The combined wafer T transferred into the wet etching apparatus 40 is delivered onto the spin chuck 110. Then, in the state that the spin chuck 110 is rotated, an etching liquid E is supplied from the liquid supply nozzle 122 while moving the liquid supply nozzle 122 in the horizontal direction, that is, within a surface of the processing target wafer W, as illustrated in FIG. 7D. As a result, the rear surface Wb of the processing target wafer W is etched (process B6 of FIG. 6). An etching condition is previously programmed.

Further, in the process B6, at the same time as the etching liquid E is supplied from the liquid supply nozzle 122, the infrared light L1 is radiated from the sensor 150 to the rear surface Wb of the processing target wafer W, and the reflection light L2 is received by the sensor 150. Then, the thickness of the processing target wafer W is calculated by the operation unit 151. In this case, an etching position and a thickness measurement position of the processing target wafer W are coincident. Thus, it is possible to measure the thickness of the processing target wafer W during the etching processing.

Furthermore, in the process B6, the etching condition is controlled based on the thickness measurement data obtained by the sensor 150 and the operation unit 151. The etching condition includes, by way of example, a position of the liquid supply nozzle 122, a supply amount of the etching liquid E, a supply time of the etching liquid E, a rotation number of the spin chuck 110, and so forth. In this case, since the etching condition is controlled in real time, an etching amount at a position of the processing target wafer W having a large thickness (for example, a position where the etching amount is small) can be increased. Meanwhile, an etching amount at a position of the processing target wafer W having a small thickness (for example, a position where the etching amount is large) can be reduced. As a result, the etching amount can be uniformed within the surface of the wafer, so that the thickness of the processing target wafer W can be uniformed within the surface thereof.

Then, upon the completion of the etching processing, the liquid supply nozzle 122 is moved to a position above the central portion of the processing target wafer W. By controlling the valves 144 and 146, the liquid supplied from the liquid supply nozzle 122 is switched into a rinse liquid R from the etching liquid E. Then, as shown in FIG. 7E, the rinse liquid R is supplied from the liquid supply nozzle 122 in the state that the spin chuck 110 is rotated. As a consequence, the rear surface Wb of the processing target wafer W is rinsed (process B7 of FIG. 6).

In the process B7, at the same time as the rinse liquid R is supplied from the liquid supply nozzle 122, the infrared light L1 is radiated from the sensor 150 to the rear surface Wb of the processing target wafer W, and the reflection light L2 is received by the sensor 150. Then, the thickness of the processing target wafer W is calculated by the operation unit 151. In this case, an etching position of the processing target wafer W and the thickness measurement position are coincident. Thus, the thickness of the processing target wafer W can be measured during the rinsing processing.

If the thickness of the processing target wafer W measured in the process B7 is normal, the processing in the wet etching apparatus 40 is completed. Meanwhile, if the thickness of the processing target wafer W measured in the process B7 is abnormal, the etching processing of the process B6 may be performed again.

Furthermore, in the present exemplary embodiment, the combined wafer T may be transferred into the wet etching apparatuses 40 and 41 in sequence, and the rear surface Wb may be wet-etched in two stages.

Thereafter, the combined wafer T after being subjected to all the processings required is transferred into the transition device 34 by the wafer transfer device 32, and then transferred into the cassette Ct on the cassette placing table 10 by the wafer transfer device 22. Then, the series of processes of the wafer processing in the wafer processing system 1 are completed.

According to the above-described exemplary embodiment, the thickness of the processing target wafer W is measured by the sensor 150 and the operation unit 151 while moving the liquid supply nozzle 122 and the sensor 150 within the surface of the processing target wafer W as one body in the process B6. Accordingly, in the etching processing, the thickness of the processing target wafer W at the position being etched can be measured. Since the thickness of the processing target wafer W can be measured within the entire surface thereof in this way, the etching processing can be uniformed within the surface of the wafer.

Further, since the etching condition is controlled in real time during the etching processing of the process B6 based on the thickness measurement data of the processing target wafer W, the etching amount can be further uniformed within the surface of the wafer. As a result, the thickness of the processing target wafer W can be uniformed within the surface thereof.

Moreover, in the rinsing processing of the process B7, the thickness of the processing target wafer W is measured and it is investigated whether or not the measured thickness is normal. Thus, the thickness of the processing target wafer W can be further uniformed within the surface thereof.

In addition, though the etching condition is controlled by measuring the thickness of the processing target wafer W during the etching processing and the rinsing processing in the present exemplary embodiment, the timing for measuring the thickness of the processing target wafer W and the control target may not be limited thereto.

By way of example, the thickness of the processing target wafer W may be measured in the rinsing processing of the process B7, and, based on this thickness measurement data, an etching condition of a next processing target wafer W may be controlled. Alternatively, the thickness of the processing target wafer W may be measured both in the etching processing of the process B6 and in the rinsing processing of the process B7, and, based on the corresponding thickness measurement data, the etching condition for the processing target wafer W may be controlled. Still alternatively, the thickness of the processing target wafer W may be measured before the etching processing of the process B6, that is, before the etching liquid is supplied onto the processing target wafer W, and the etching condition may be controlled based on this thickness measurement data.

For example, the thickness of the next processing target wafer W may be measured before the etching processing of the process B6, and, based on this thickness measurement data, search criteria in the grinding apparatus 50 may be controlled. Specifically, one or all of a rough grinding condition of the process B3, an intermediate grinding condition of the process B4 and a finishing grinding condition of the process B5 may be controlled, for example. Furthermore, the thickness measurement data obtained in the rinsing processing of the process B7 may be outputted to the grinding apparatus 50 after the etching processing. In this case, a condition for a film thickness after the grinding is changed without changing the etching recipe (etching condition). Moreover, the thickness of the processing target wafer W may be measured in the grinding apparatus 50, and the etching condition may be controlled based on this thickness measurement data.

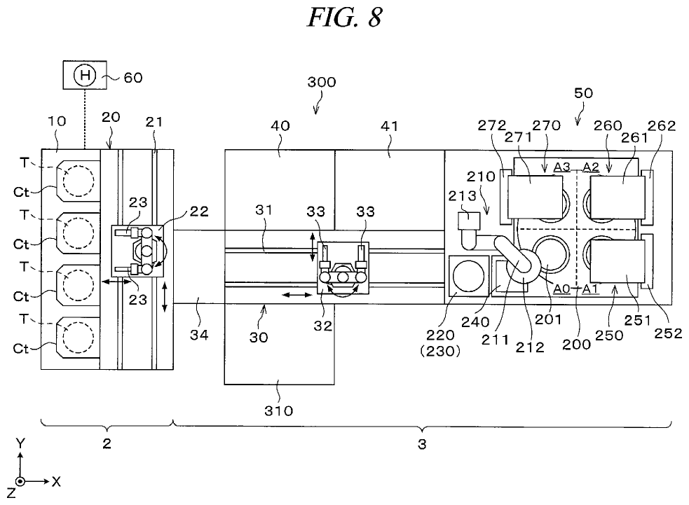

Now, a configuration of a wafer processing system according to a second exemplary embodiment will be explained. FIG. 8 is a plan view schematically illustrating a configuration of a wafer processing system 300.

The wafer processing system 300 further includes a CMP (Chemical Mechanical Polishing) apparatus 310 in addition to the components of the wafer processing system 1 according to the first exemplary embodiment. The CMP apparatus 310 is configured to polish the rear surface Wb of the processing target wafer W after being subjected to the etching processing. The CMP apparatus 310 is provided at a negative Y-axis side of the wafer transfer section 30 in the processing station 3, for example.

After the rinsing processing of the process B7 is performed in a wet etching apparatus 40, the combined wafer T is transferred into the CMP apparatus 310 by the wafer transfer device 32, and the rear surface Wb is polished therein.

In this case, the thickness of the processing target wafer W is measured in the rinsing processing of the process B7, and a polishing condition of the CMP apparatus 310 may be controlled based on this thickness measurement data.

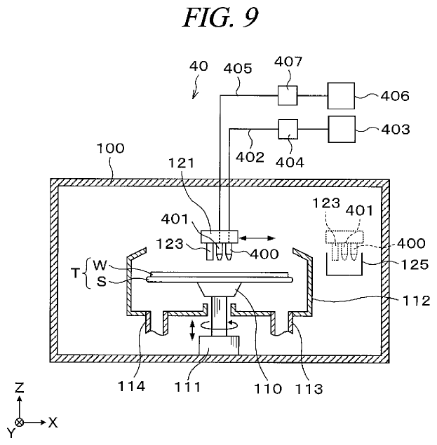

In the wet etching apparatus 40 according to the first and second exemplary embodiments, though the etching liquid E and the rinse liquid R are supplied from the single liquid supply nozzle 122 while being switched, the etching liquid E and the rinse liquid R may be supplied from separate liquid supply nozzles. In such a case, as illustrated in FIG. 9, in the wet etching apparatus 40, the arm 121 may be equipped with a first liquid supply nozzle 400 configured to supply the etching liquid E and a second liquid supply nozzle 401 configured to supply the rinse liquid R.

The first liquid supply nozzle 400 has the same configuration as the liquid supply nozzle 122 except that it is connected to a supply line 402 instead of the supply line 140. The supply line 402 communicates with an etching liquid source 403 which stores therein the etching liquid E. Further, the supply line 402 is provided with a valve 404 configured to control a supply of the etching liquid E. Furthermore, the first liquid supply nozzle 400 is equipped with a sensor 150 and an operation unit 151, and, thus, it is possible to measure the thickness of the processing target wafer W.

The second liquid supply nozzle 401 also has the same configuration as the liquid supply nozzle 122 except that it is connected to a supply line 405 instead of the supply line 140. The supply line 405 communicates with a rinse liquid source 406 which stores therein the rinse liquid R. Further, the supply line 405 is provided with a valve 407 configured to control a supply of the rinse liquid R. Furthermore, the second liquid supply nozzle 401 is equipped with a sensor 150 and an operation unit 151, and, thus, it is possible to measure the thickness of the processing target wafer W.

Further, the arm 121 may be equipped with another liquid supply nozzle (not shown) which has neither the sensor 150 nor the operation unit 151. This liquid supply nozzle may be a nozzle configured to supply the etching liquid E or the rinse liquid R, or a nozzle configured to supply both the etching liquid E and the rinse liquid R while switching them.

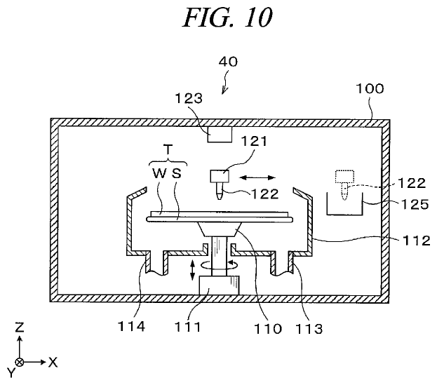

Moreover, though the temperature measurement device 123 is supported at the arm 121 in the wet etching apparatus 40 according to the first and second exemplary embodiments, an installation place for the temperature measurement device 123 may not be limited thereto. By way of example, as illustrated in FIG. 10, the temperature measurement device 123 may be provided at a ceiling surface of the processing vessel 100 to be located above the combined wafer T held by the spin chuck 110.

Further, in the above-described wafer processing system 1 (300), though the bonding of the processing target wafer W and the support wafer S is performed by the bonding apparatus provided at the outside of the wafer processing system 1 (300), this bonding apparatus may be provided within the wafer processing system 1 (300). In such a configuration, cassettes Cw, Cs and Ct respectively capable of accommodating therein a multiple number of processing target wafers W, a multiple number of support wafers S and a multiple number of combined wafers T are carried to/from the carry-in/out station 2. These cassettes Cw, Cs and Ct can be arranged in a row in the X-axis direction on the cassette placing table 10.

In addition, in the above-described first and second exemplary embodiments, though the wet etching apparatus 40 performs the etching processing upon the processing target wafer W after being subjected to the grinding processing in the grinding apparatus 50, the processing target of the wet etching apparatus 40 may not be limited thereto. By way of example, the wet etching apparatus 40 of the present exemplary embodiments may be used in an etching processing in, for example, a photolithography process.

So far, the exemplary embodiments have been described. However, it should be noted that the above-described exemplary embodiments are illustrative in all aspects and are not anyway limiting. The above-described exemplary embodiments may be omitted, replaced and modified in various ways without departing from the scope and the spirit of claims.

### EXPLANATION OF CODES

1: Wafer processing system
40, 41: Wet etching apparatus
60: Control device
120: Rail
121: Arm
122: Liquid supply nozzle
124: Driving unit
150: Sensor
S: Support wafer
T: Combined wafer
W: Processing target wafer

1. A substrate processing system configured to process a substrate, comprising:
an etching apparatus configured to etch the substrate; and
a control device configured to control the etching apparatus,
wherein the etching apparatus comprises:
a liquid supply nozzle configured to supply a processing liquid onto the substrate;
a thickness measurement device provided as one body with the liquid supply nozzle, and configured to measure a thickness of the substrate without being in contact with the substrate; and
a moving mechanism configured to move the liquid supply nozzle and the thickness measurement device in a horizontal direction, and
wherein the control device controls the liquid supply nozzle, the thickness measurement device and the moving mechanism such that the thickness of the substrate is measured by the thickness measurement device while the liquid supply nozzle and the thickness measurement device are being moved in the horizontal direction.

2. The substrate processing system of claim 1,
wherein the processing liquid is an etching liquid, and
the control device controls the liquid supply nozzle, the thickness measurement device and the moving mechanism such that the thickness of the substrate is measured by the thickness measurement device in an etching processing of the substrate with the etching liquid supplied from the liquid supply nozzle.

3. The substrate processing system of claim 1,
wherein the processing liquid is a rinse liquid, and
the control device controls the liquid supply nozzle, the thickness measurement device and the moving mechanism such that the thickness of the substrate is measured by the thickness measurement device in a rinsing processing of the substrate, which is performed after an etching processing of the substrate, with the rinse liquid supplied from the liquid supply nozzle.

4. The substrate processing system of claim 1,
wherein the processing liquid includes an etching liquid and a rinse liquid, and
the control device controls the liquid supply nozzle, the thickness measurement device and the moving mechanism such that the thickness of the substrate is measured by the thickness measurement device in an etching processing of the substrate with the etching liquid supplied from the liquid supply nozzle and in a rinsing processing of the substrate, which is performed after the etching processing of the substrate, with the rinse liquid supplied from the liquid supply nozzle.

5. The substrate processing system of claim 4,
wherein the etching liquid and the rinse liquid are supplied to the liquid supply nozzle while being switched, and
the thickness of the substrate is measured by the common thickness measurement device in each of the etching processing and the rinsing processing.

6. The substrate processing system of claim 4,
wherein the liquid supply nozzle comprises a first liquid supply nozzle configured to supply the etching liquid and a second liquid supply nozzle configured to supply the rinse liquid, and
the thickness measurement device is provided in each of the first liquid supply nozzle and the second liquid supply nozzle.

7. The substrate processing system of claim 1,
wherein the etching apparatus comprises a temperature measurement device configured to measure a temperature of the substrate, and
the control device corrects a measurement of the thickness of the substrate in the thickness measurement device based on temperature measurement data of the temperature measurement device.

8. The substrate processing system of claim 1,
wherein the control device controls an etching condition of the etching apparatus based on thickness measurement data obtained by the thickness measurement device.

9. The substrate processing system of claim 1, further comprising:
a grinding apparatus configured to grind a surface of the substrate,
wherein the etching apparatus etches the surface of the substrate ground by the grinding apparatus, and
the control device controls a grinding condition of the grinding apparatus based on thickness measurement data obtained by the thickness measurement device before or after an etching processing.

10. The substrate processing system of claim 1, further comprising:
a polishing apparatus configured to polish, after a surface of the substrate is etched by the etching apparatus, the surface of the substrate,
wherein the control device controls a polishing condition of the polishing apparatus based on thickness measurement data obtained by the thickness measurement device after an etching processing.

11. A substrate processing method of processing a substrate, comprising:
etching the substrate by using an etching apparatus,
wherein the etching apparatus comprises:
a liquid supply nozzle configured to supply a processing liquid onto the substrate;
a thickness measurement device provided as one body with the liquid supply nozzle, and configured to measure a thickness of the substrate without being in contact with the substrate; and
a moving mechanism configured to move the liquid supply nozzle and the thickness measurement device in a horizontal direction, and
wherein in the etching of the substrate, the thickness of the substrate is measured by the thickness measurement device while the liquid supply nozzle and the thickness measurement device are being moved in the horizontal direction.

12. The substrate processing method of claim 11,
wherein the processing liquid is an etching liquid, and
in the etching of the substrate, the thickness of the substrate is measured by the thickness measurement device in an etching processing of the substrate with the etching liquid supplied from the liquid supply nozzle.

13. The substrate processing method of claim 11,
wherein the processing liquid is a rinse liquid, and
in the etching of the substrate, the thickness of the substrate is measured by the thickness measurement device in a rinsing processing, which is performed after an etching processing of the substrate, with the rinse liquid supplied from the liquid supply nozzle.

14. The substrate processing method of claim 11,
wherein the processing liquid includes an etching liquid and a rinse liquid, and
in the etching of the substrate, the thickness of the substrate is measured by the thickness measurement device in an etching processing of the substrate with the etching liquid supplied from the liquid supply nozzle and in a rinsing processing of the substrate, which is performed after the etching processing of the substrate, with the rinse liquid supplied from the liquid supply nozzle.

15. The substrate processing method of claim 14,
wherein the etching liquid and the rinse liquid are supplied to the liquid supply nozzle while being switched, and
in the etching of the substrate, the thickness of the substrate is measured by the common thickness measurement device in each of the etching processing and the rinsing processing.

16. The substrate processing method of claim 14,
wherein the liquid supply nozzle comprises a first liquid supply nozzle configured to supply the etching liquid and a second liquid supply nozzle configured to supply the rinse liquid,
the thickness measurement device is provided in each of the first liquid supply nozzle and the second liquid supply nozzle, and
in the etching of the substrate, the thickness of the substrate is measured by the thickness measurement device in the etching processing of the substrate with the etching liquid supplied from the first liquid supply nozzle and in the rinsing processing of the substrate, which is performed after the etching processing of the substrate, with the rinse liquid supplied from the second liquid supply nozzle.

17. The substrate processing method of claim 11,
wherein the etching apparatus comprises a temperature measurement device configured to measure a temperature of the substrate, and
in the etching of the substrate, a measurement of the thickness of the substrate in the thickness measurement device is corrected based on temperature measurement data of the temperature measurement device.

18. The substrate processing method of claim 11,
wherein in the etching of the substrate, an etching condition for the substrate is controlled based on thickness measurement data obtained by the thickness measurement device.

19. The substrate processing method of claim 11, further comprising:
grinding a surface of the substrate,
wherein in the etching of the substrate, the ground surface of the substrate is etched, and
a grinding condition for the substrate is controlled based on thickness measurement data obtained by the thickness measurement device before or after an etching processing.

20. The substrate processing method of claim 11, further comprising:
polishing, after a surface of the substrate is etched, the surface of the substrate,
wherein in the etching of the substrate, a polishing condition for the substrate is controlled based on thickness measurement data obtained by the thickness measurement device after an etching processing.
